(19) United States
(12) Patent Application Publication
(10) Pub. No.: US 2024/0150649 A1
(43) Pub. Date: May 9, 2024

(54) ELECTROLUMINESCENT ELEMENT, LIGHT EMITTING DEVICE, AND PRODUCTION METHOD FOR ELECTROLUMINESCENT ELEMENT

(71) Applicants: Sharp Kabushiki Kaisha, Sakai City, Osaka (JP); TOPPAN INC., Tokyo (JP)

(72) Inventors: Kazuki GOTO, Sakai City (JP); Yusuke SAKAKIBARA, Sakai City (JP); Masaki YAMAMOTO, Sakai City (JP); Tatsuya RYOHWA, Sakai City (JP); Akio MISHIMA, Chikushino-city (JP); Soichiro NIKATA, Chikushino-city (JP); Vit KALOUSEK, Chikushino-city (JP); Yuko OGURA, Chikushino-city (JP); Yoko MICHIWAKI, Chikushino-city (JP)

(21) Appl. No.: 18/284,182

(22) PCT Filed: Mar. 31, 2021
(86) PCT No.: PCT/JP2021/013864

§ 371 Date: Sep. 26, 2023

(51) Int. Cl. C09K 11/88; C09K 11/08; C09K 11/58; C09K 11/62

(52) U.S. Cl. CPC C09K 11/88; C09K 11/0811; C09K 11/58; C09K 11/621

(57) ABSTRACT

A light-emitting element includes an anode electrode, a QD layer containing QDs, and a cathode electrode, in which the QDs are Cd-free quantum dots having a core-shell structure including a core containing at least Ag, Ga, and at least one of S and Se, and a shell containing at least Zn, and exhibit fluorescence characteristics with a fluorescence full-width at half-maximum of 40 nm or less and a fluorescence quantum yield percentage of 70% or more.

### TECHNICAL FIELD

The disclosure relates to electroluminescent elements and light-emitting devices containing Cd-free quantum dots having a core-shell structure, and methods for manufacturing the electroluminescent elements.

### BACKGROUND ART

In recent years, various features related to electroluminescent elements containing quantum dots have been developed.

Cd-based quantum dots containing cadmium (Cd) are commonly used as the quantum dots. Quantum dots containing Cd have advantages of high fluorescence quantum yield and a narrow fluorescence full-width at half-maximum. On the other hand, Cd is internationally regulated due to its negative impact on the environment, and thus barriers for practical use are high.

Therefore, in recent years, development of Cd-free quantum dots that do not substantially contain Cd has also been promoted. PTLs 1 to 5 and NPLs 1 to 4 below disclose, as Cd-free quantum dots, for example, AIS quantum dots containing silver (Ag), indium (In), and sulfur (S); AIGS quantum dots containing Ag, In, gallium (Ga), and S; AlSe quantum dots containing Ag, In, and selenium (Se); AlGSe quantum dots containing Ag, In, Ga, and Se; AGS quantum dots containing Ag, Ga, and S; and AGSe quantum dots containing Ag, Ga, and Se.

### CITATION LIST

### Patent Literature

PTL 1: JP 2017-025201 A
PTL 2: JP 2018-039971 A
PTL 3: JP 2018-044142 A
PTL 4: JP 2018-141141 A
PTL 5: WO 2018/159699

### Non Patent Literature

NPL 1: NPG Asia Materials volume 10. 2018, pp 713-726
NPL 2: ACS Publications 2018, 10, 49, 41844-41855
NPL 3: ACS Publications Nano Mater. 2020, 3, 3275-3287
NPL 4: The Journal of Physical Chemistry Letters; Ligand-Induced Luminescence Transformation in AgInS2 Nanoparticles: From Defect Emission to Band-Edge Emission

### SUMMARY

### Technical Problem

PTLs 1, 3, and the like disclose a use of Zn in cores (e.g., AgGaS or AgInGaS) of chalcopyrite quantum-dots such as AGS quantum dots or AIGS quantum dots.

However, when Zn is used in AgGaS or AgInGaS as described above, a difference in valence between Zn and metal atoms, which are cation species, (e.g., Zn is divalent, Ag is monovalent, and Ga and In are trivalent) results in defect emission, and a fluorescence full-width at half-maximum tends to widen.

Further, even when Zn is post-added so that AgGaS or AgInGaS does not contain Zn, the cation species easily diffuse in a particle. This allows Zn to easily diffuse into the core, resulting in defect emission.

An aspect of the disclosure has been made in view of the above-described problems, and provides an electroluminescent element and a light-emitting device containing quantum dots with high Zn content on their surfaces, and a method for manufacturing the electroluminescent element.

### Solution to Problem

To solve the problems described above, an electroluminescent element according to an aspect of the disclosure includes a first electrode, a second electrode, and a quantum dot light-emitting layer containing a quantum dot and provided between the first electrode and the second electrode, in which the quantum dot is a Cd-free quantum dot having a core-shell structure including a core containing at least Ag, Ga, and at least one of S and Se, and a shell containing at least Zn, and exhibits fluorescence characteristics with a fluorescence full-width at half-maximum of 40 nm or less and a fluorescence quantum yield percentage of 70% or more.

To solve the problems described above, a light-emitting device according to an aspect of the disclosure includes at least one electroluminescent element according to an aspect of the disclosure.

To solve the problems described above, in a method for manufacturing an electroluminescent element according to an aspect of the disclosure, the electroluminescent element includes a first electrode, a second electrode, and a quantum dot light-emitting layer containing a quantum dot being Cd-free, and provided between the first electrode and the second electrode. The method includes forming the first electrode, forming the quantum dot light-emitting layer containing the quantum dot, forming the second electrode, and synthesizing the quantum dot prior to the forming the quantum dot light-emitting layer, in which the synthesizing the quantum dot includes producing a core containing at least Ag, Ga, and at least one of S and Se, and forming a shell on a surface of the core, and in the forming a shell, a Ga-containing layer containing Ga and at least one of S and Se is formed on the surface of the core, and then Zn is added.

### Advantageous Effects of Disclosure

According to an aspect of the disclosure, it is possible to provide an electroluminescent element and a light-emitting device containing a quantum dot with high Zn content on a surface thereof, and a method for manufacturing the electroluminescent element.

### BRIEF DESCRIPTION OF DRAWINGS

FIG. 1 is a cross-sectional view schematically illustrating an example of an overall configuration of a light-emitting element according to a first embodiment.

FIG. 2 is a schematic view illustrating an example of a quantum dot according to the first embodiment.

FIG. 3 is a flowchart illustrating an example of an overview of a method for manufacturing the light-emitting element according to the first embodiment.

FIG. 4 is a flowchart illustrating an example of a synthesis step of the quantum dot according to the first embodiment.

FIG. 5 is a flowchart illustrating an example of a shell forming step according to the first embodiment.

FIG. 6 is a conceptual diagram illustrating an example of a manufacturing process of the quantum dot according to the first embodiment.

FIG. 7 is a conceptual diagram illustrating another example of a manufacturing process of the quantum dot according to the first embodiment.

FIG. 8 is a graph showing XRD spectra of Samples A to C obtained in the respective synthesis stages of Synthesis Example 1.

FIG. 9 is a graph showing photoluminescence (PL) spectra of quantum dots obtained in Synthesis Example 1 and Synthesis Example 2, respectively.

FIG. 10 is a diagram showing a TEM-EDX observation image of Se+S in quantum dots obtained in Synthesis Example 1.

FIG. 11 is a diagram showing a TEM-EDX observation image of Ag+Zn in the quantum dots obtained in Synthesis Example 1.

FIG. 12 is a diagram showing a STEM image of quantum dots obtained in Synthesis Example 2.

FIG. 13 is a diagram showing a TEM-EDX observation image of Ag+Zn in the quantum dots obtained in Synthesis Example 2.

FIG. 14 is a diagram showing a TEM-EDX observation image of Zn in the quantum dots obtained in Synthesis Example 1.

FIG. 15 is a diagram showing a TEM-EDX observation image of Zn in quantum dots for comparison obtained in Comparative Example.

FIG. 16 is a graph showing luminance values at 25 mA/cm² of Samples (1) to (3) obtained in Example 1.

FIG. 17 is a cross-sectional view schematically illustrating an overall configuration of main portions of a display device according to a second embodiment.

### DESCRIPTION OF EMBODIMENTS

### First Embodiment

The electroluminescent element (hereinafter, simply denoted by “light-emitting element”) according to the present embodiment will be described as follows. Note that, in the following, a description of “from A to B” for two numbers A and B is intended to mean “equal to or greater than A and equal to or less than B” unless otherwise specified.

### Structural Example of Light-Emitting Element

The light-emitting element according to the present embodiment includes a first electrode, a second electrode, and a function layer including at least a quantum dot light-emitting layer containing quantum dots (hereinafter, simply referred to as “quantum dot layer”) provided between the first electrode and the second electrode. One and the other of the first electrode and the second electrode are an anode electrode and a cathode electrode. Quantum dots emit light in accordance with a combination of positive holes (holes) supplied from the anode electrode (anode) and electrons (free electrons) supplied from the cathode electrode (cathode). Note that, in the present embodiment, the layers between the anode electrode and the cathode electrode are collectively referred to as a function layer.

Examples of the light-emitting element include a quantum dot light-emitting diode (QLED). Note that hereinafter, a quantum dot is abbreviated as “QD”. Therefore, the quantum dot layer (quantum dot light-emitting layer) is abbreviated as a “QD layer (QD light-emitting layer)”.

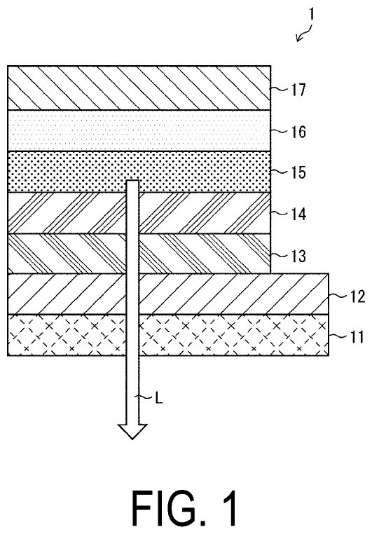

FIG. 1 is a cross-sectional view schematically illustrating an example of an overall configuration of a light-emitting element 1 according to the present embodiment.

As illustrated in FIG. 1, the light-emitting element 1 includes an anode electrode 12 (anode), a cathode electrode 17 (cathode), and a function layer provided between the anode electrode 12 and the cathode electrode 17. The function layer includes at least a QD layer 15 (QD light-emitting layer) containing QDs.

The function layer may be a single layer type formed only of the QD layer 15, or may be a multi-layer type including a function layer in addition to the QD layer 15. Of the function layer, examples of function layers besides the QD layer 15 include a hole injection layer (hereinafter, denoted by “HIL”), a hole transport layer (hereinafter, denoted by “HTL”), and an electron transport layer (hereinafter, denoted by “ETL”).

Note that in the disclosure, a direction from the anode electrode 12 to the cathode electrode 17 in FIG. 1 is referred to as an upward direction, and the opposite direction thereof is referred to as a downward direction. In the disclosure, a horizontal direction is a direction (main surface direction of each portion included in the light-emitting element 1) perpendicular to a vertical direction. The vertical direction can also be referred to as a normal direction of each portion described above.

Each layer from the anode electrode 12 to the cathode electrode 17 is generally supported by a substrate used as a support body. Accordingly, the light-emitting element 1 may be provided with a substrate as a support body.

As one example, the light-emitting element 1 illustrated in FIG. 1 has a configuration in which a substrate 11, the anode electrode 12, an HIL 13, an HTL 14, the QD layer 15, an ETL 16, and the cathode electrode 17 are layered in this order towards the upward direction of FIG. 1.

Hereinafter, each layer described above will be described in greater detail.

The substrate 11 is a support body for forming each layer from the anode electrode 12 to the cathode electrode 17, as described above.

Note that the light-emitting element 1 may be used, for example, as a light source of an electronic device such as a display device. When the light-emitting element 1 is a part of a display device, for example, a substrate of the display device is used as the substrate 11. Thus, the light-emitting element 1 may be referred to as the light-emitting element 1 including the substrate 11, or may be referred to as the light-emitting element 1 not including the substrate 11.

In this manner, the light-emitting element 1 itself may include a substrate 11, or the substrate 11 of the light-emitting element 1 may be a substrate of an electronic device such as a display device provided with the light-emitting element 1. When the light-emitting element 1 is a part of a display device, for example, an array substrate on which a plurality of thin film transistors are formed may be used as the substrate 11. In this case, the anode electrode 12, which is a first electrode provided on the substrate 11, may be electrically connected to the thin film transistors (TFTs) of the array substrate.

In the case where the light-emitting element 1 is, for example, a part of a display device in this manner, the light-emitting element 1 is provided as a light source on the substrate 11 for each pixel. Specifically, a red pixel (R pixel) is provided with, as a red light source, a light-emitting element (red light-emitting element) that emits red light. A green pixel (G pixel) is provided with, as a green light source, a light-emitting element (green light-emitting element) that emits green light. A blue pixel (B pixel) is provided with, as a blue light source, a light-emitting element (blue light-emitting element) that emits blue light. Accordingly, a bank partitioning the pixels may be formed as a pixel separation film such that the light-emitting elements can be formed on the substrate 11 for each R pixel, G pixel, and B pixel (i.e., RGB patterning can be performed).

In a bottom-emitting (BE) type light-emitting element having a BE structure, light emitted from the QD layer 15 is emitted downward (i.e., towards the substrate 11 side). In a top-emitting (TE) type light-emitting element having a TE structure, light emitted from the QD layer 15 is emitted upward (i.e., towards the side opposite the substrate 11). In a double-sided light-emitting element, the light emitted from the QD layer 15 is emitted downward and upward.

In a case where the light-emitting element 1 is a BE type light-emitting element or a double-sided light-emitting element, the substrate 11 is constituted of a transparent substrate having relatively high translucency such as a glass substrate, for example.

On the other hand, in a case where the light-emitting element 1 is a TE type light-emitting element, the substrate 11 may be constituted of a substrate having relatively low translucency such as a plastic substrate, or may be constituted of a light-reflective substrate having light reflectivity, for example. Note that, the TE structure has few light blocking elements such as TFTs on the light-emitting face, so that the aperture ratio can be made high and the external quantum efficiency (EQE) can be made higher.

Of the anode electrode 12 and the cathode electrode 17, the electrode on the light output face side must be light-transmissive. Also note that the electrode of the side opposite the light output face may or may not be light-transmissive.

For example, when the light-emitting element 1 is a BE type light-emitting element, the electrode on the upper-layer side is a light reflective electrode, and the electrode on the lower-layer side is a light-transmissive electrode. When the light-emitting element 1 is a TE type light-emitting element, the electrode on the upper-layer side is a light-transmissive electrode, and the electrode on the lower-layer side is a light reflective electrode. Note that the light reflective electrode may be a layered body of a layer formed of a light-transmissive material and a layer formed of a light-reflective material.

In FIG. 1, as one example, a case is illustrated in which the light-emitting element 1 is the BE type light-emitting element in which the anode electrode 12 is used as the electrode on the lower-layer side (lower-layer electrode), the cathode electrode 17 is used as the electrode on the upper-layer side (upper-layer electrode), and light L emitted from the QD layer 15 is emitted downward. Therefore, a light-transmissive electrode is used as the anode electrode 12 such that the light L emitted from the QD layer 15 can pass through the anode electrode 12. Further, a light reflective electrode is used as the cathode electrode 17 such that the light L emitted from the QD layer 15 is reflected.

The anode electrode 12 is an electrode that supplies positive holes (holes) to the QD layer 15 when a voltage is applied. The anode electrode 12 is made of, for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 17 is an electrode that supplies electrons to the QD layer 15 when a voltage is applied to the cathode electrode 17. The cathode electrode 17 is made of, for example, a material having a relatively small work function. Examples of the material include aluminum (Al), silver (Ag), barium (Ba), ytterbium (Yb), calcium (Ca), lithium (Li)—Al alloys, magnesium (Mg)—Al alloys, Mg—Ag alloys, Mg-indium (In) alloys, and Al-aluminum oxide (Al₂O₃) alloys.

The HIL 13 is a layer that transports positive holes supplied from the anode electrode 12 to the HTL 14. A hole transport material is used for a material of the HIL 13. The hole transport material may be an organic material or an inorganic material. When the hole transport material is an organic material, examples of the organic material include an electrically conductive polymer material. As the polymer material, for example, a composite (PEDOT:PSS) of poly(3,4-ethylenedioxythiophene) (PEDOT) and polystyrene sulfonic acid (PSS) can be used. Only one type of these hole transport materials may be used, or two or more types thereof may be appropriately mixed and used. The HIL 13 preferably contains PEDOT:PSS among the above-described polymer materials. Thus, the light-emitting element 1 that has high hole mobility and can obtain favorable light-emission characteristics can be provided.

The HTL 14 is a layer that transports positive holes supplied from the HIL 13, to the QD layer 15. A hole transport material is used for a material of the HTL 14. The hole transport material may be an organic material or an inorganic material. In general, an organic material is used. When the hole transport material is an organic material, examples of the organic material include an electrically conductive polymer material. As the polymer material, for example, poly[(9,9-dioctylfluorenyl-2,7-diyl)-co-(4,4′-(N-(4-sec-butylphenyl)diphenylamine))] (TFB) and poly(N-vinylcarbazole) (PVK) can be used. Only one type of these hole transport materials may be used, or two or more types thereof may be appropriately mixed and used.

Of the above-described hole transport materials, the HTL 14 preferably contains TFB. This provides the light-emitting element 1 with higher light emission luminance and more favorable light-emission characteristics than when other hole transport materials such as PVK are used as the hole transport material.

Note that, in a case where positive holes can be sufficiently supplied to the QD layer 15 only by the HTL 14, the HIL 13 need not be provided.

The ETL 16 is a layer that transports electrons supplied from the cathode electrode 17 to the QD layer 15. An electron transport material is used for a material of the ETL 16. The electron transport material may be an organic material or an inorganic material. When the electron transport material is an organic material, the organic material preferably contains at least one type of compound selected from the group consisting of 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB), for example. A single type of these organic materials may be used alone, or two or more types may be mixed and used, as appropriate.

When the electron transport material is an inorganic material, the inorganic material is preferably nanoparticles composed of a metal oxide containing at least one element selected from the group consisting of zinc (Zn), magnesium (Mg), titanium (Ti), silicon (Si), tin (Sn), tungsten (W), tantalum (Ta), barium (Ba), zirconium (Zr), aluminum (Al), yttrium (Y), and hafnium (Hf). As such a metal oxide, for example, zinc oxide (ZnO), zinc magnesium oxide (ZnMgO), or the like is preferably used. A single type of these metal oxides may be used alone, or two or more types may be mixed and used, as appropriate.

Of the above-described electron transport materials, the ETL 16 preferably contains ZnMgO. This provides the light-emitting element 1 with higher light emission luminance and more favorable light-emission characteristics than when other electron transport materials such as ZnO are used as the electron transport material.

The QD layer 15 is a layer that contains the QDs as the light-emitting material and emits the light L as a result of a combination of the positive holes supplied from the anode electrode 12 and the electrons (free electrons) supplied from the cathode electrode 17. That is, the QD layer 15 emits light through electroluminescence (EL). More specifically, the QD layer 15 emits light through injection type EL.

The QDs are inorganic nanoparticles composed of about several thousands to several tens of thousands of atoms and having a particle size of about several nm to a dozen nm. The QDs emit fluorescence and are nano order in size, and thus the QDs are also referred to as fluorescent nanoparticles or QD phosphor particles. A composition of the QDs is derived from a semiconductor material, and thus the QDs are also referred to as semiconductor nanoparticles. The QDs have a structure having a specific crystal structure, and thus the QDs are also referred to as nanocrystals. Thus, the QD layer (QD light-emitting layer) is also referred to as, for example, a QD phosphor layer.

The QD is constituted of metal atoms, which are cation species (cation raw material) having a positive charge, and non-metal or metalloid atoms, which are anion species (anion raw material) having a negative charge. The metal atom and the metalloid atom are bonded to each other by an ionic bond or a covalent bond. Ionic bonding properties of the bond depend on a combination of properties of the metal atom and the metalloid atom.

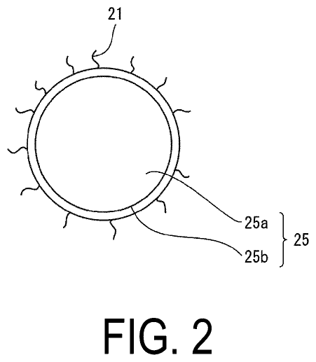

The light-emitting element 1 contains, for example, QDs 25 illustrated in FIG. 2 as QDs in the QD layer 15. FIG. 2 is a schematic view illustrating an example of the QD 25 according to the present embodiment. The QDs 25 according to the present embodiment are Cd-free nanocrystals that do not substantially contain Cd.

Note that, in the disclosure, the term “nanocrystal” refers to a nanoparticle having a particle size from about several nm to several tens of nm. In the present embodiment, a large number of QDs 25 can be produced with a substantially uniform particle size.

Further, in the disclosure, “substantially free of Cd” or “Cd-free” means that the QDs 25 do not contain Cd in a mass ratio of 1/30 or more with respect to a total amount of metal atoms as its cation species. Therefore, the term “substantially free of Cd” or “Cd-free” means that the QDs 25 preferably do not contain Cd in the mass ratio of 1/30 or more with respect to the total amount of Ag and Ga.

As illustrated in FIG. 2, each QD 25 according to the present embodiment has a core-shell structure including a core 25a and a shell 25b.

The core 25a is preferably a nanocrystal containing at least silver (Ag), gallium (Ga), and at least one of sulfur (S) and selenium (Se) (i.e., a nanocrystal made of any of materials AgGaSₚSe₂₋ₚ (0≤p≤2)). Among them, the core 25a is more preferably a nanocrystal containing at least Ag, Ga, and S, or a nanocrystal containing at least Ag, Ga, and Se, and particularly preferably a nanocrystal containing Ag, Ga, and Se. The core 25a may also contain at least one of copper (Cu) and indium (In). However, the core 25a preferably does not contain cadmium (Cd) or In.

The shell 25b is provided on a surface of the core 25a and covers at least part of the surface of the core 25a. Note that it is particularly desirable that the shell 25b cover an entire surface of the core 25a.

The QD 25 can be said to have a core-shell structure when it is found that the shell 25b surrounds the core 25a by observing one cross section of the QD 25. For example, from cross section observation of 50 QDs 25 adjacent to each other, a mean value of diameters of circles having areas corresponding to areas of cross-section of the QDs 25 (assumed dot diameter) is calculated. At this time, when a difference between the assumed dot diameter and the assumed core diameter is 0.3 nm or more, it can be said that the shell 25b envelops the core 25a (covers the entire core 25a). Note that the cross-section observation can be performed with, for example, a scanning transmission electron microscope (STEM).

The shell 25b contains at least zinc (Zn). Similar to the core 25a, the shell 25b preferably does not contain Cd or In. Thus, it is preferable to use raw materials that do not contain Cd or In as a raw material for the core 25a and a raw material for the shell 25b.

In the present embodiment, the shell 25b contains a large amount of Zn. To be specific, the shell 25b preferably contains at least one selected from the group consisting of zinc sulfide (ZnS), zinc selenide (ZnSe), zinc gallium selenide (ZnGa₂Se₄), and zinc gallium sulfide (ZnGa₂S₄). The shell 25b may be made of any one selected from the group consisting of ZnS, ZnSe, ZnGa₂S₄, and ZnGa₂Se₄. Among them, ZnS is preferable. Note that the shell 25b may be in a solid solution state on the surface of the core 25a.

Examples of indicators of QD performance include fluorescence quantum yield and a fluorescence full-width at half-maximum (FWHM). In the present embodiment, by making the QD 25 have the core-shell structure as described above, an increase in the fluorescence quantum yield can be expected while keeping the fluorescence full-width at half-maximum narrow.

In the QD 25 of the present embodiment, the surface of the core 25a of AgGaSe or AgGaS can be appropriately covered with the shell 25b of, for example, ZnS, ZnSe, ZnGa₂S₄, or ZnGa₂Se₄. In the present embodiment, diffusion of Ag contained in the core 25a into the shell 25b is prevented. When the core 25a contains one of S and Se and the shell 25b contains another, the one of S and Se contained in the core 25a and the other of S and Se contained in the shell 25b can be appropriately separated. For example, when the core 25a contains Se, the Se contained in the core 25a and the S contained in the shell 25b can be separated appropriately.

In the present embodiment, the shell 25b may further contain gallium (Ga). Ga may be distributed throughout the shell 25b, or may be unevenly distributed in the shell 25b. For example, when the shell 25b is composed of multiple layers and a layer adjacent to the core 25a is the innermost layer of the shell 25b (first layer of the shell), GaS may be interposed between the core 25a and a layer (e.g., the outermost layer) located outside the innermost layer in the shell 25b.

In the present embodiment, an amount of Zn present on the surface of the QD 25 can be increased. To be specific, the amount of Zn is 2% or more, preferably 5% or more, and more preferably 10% or more by weight relative to the entire QD 25. Although an upper limit is not limited, for example, an upper limit is about 40%.

As illustrated in FIG. 2, numerous ligands 21 are preferably coordinated (adsorbed) on the surface of the QD 25 as ligands. The ligand 21 is a surface-modifying group that modifies the surface of the QD 25. The QD layer 15 formed by the solution method contains the spherical QDs 25 and the ligands 21. By coordinating the ligands 21 on the surfaces of the QDs 25, aggregation of the QDs 25 can be suppressed, and thus target optical characteristics are easily exhibited. The ligands 21 that can be used for reaction (i.e., the ligands 21 to be coordinated to the surface of QD 25) are not limited, but are preferably organic ligands. Inorganic ligands are preferably coordinated with organic ligands on the surface of the QD 25. Accordingly, defects on the surfaces of the QDs 25 can be further suppressed, and higher optical characteristics can be exhibited.

The organic ligands are not limited, and representative examples thereof include amine-based (e.g., aliphatic primary amine-based), fatty acid-based, thiol-based, phosphine-based, phosphine oxide-based, and alcohol-based ligands.

Examples of the amine-based ligands 21 include aliphatic primary amine-based ligands. Examples of the aliphatic primary amine-based ligands include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of the fatty acid-based ligands 21 include oleic acid (C₁₇H₃₃COOH), stearic acid (C₁₇H₃₅COOH), palmitic acid (C₁₅H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of the thiol-based ligands 21 include octadecanethiol (C₁₈H₃₇SH), hexanedecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Examples of the phosphine-based ligands 21 include trioctylphosphine ((C₈H₁₇)₃P), triphenylphosphine ((C₆H₅)₃P), and tributyl phosphine ((C₄H₉)₃P).

Examples of the phosphine oxide-based ligands 21 include trioctylphosphine oxide ((C₈H₁₇)₃P═O), triphenylphosphine oxide ((C₆H₅)₃P═O), and tributyl phosphine oxide ((C₄H₉)₃P═O).

Examples of the alcohol-based ligands 21 include oleyl alcohol (C₁₈H₃₆O).

The inorganic ligands are not limited, and representative examples thereof include halogens such as fluorine (F), chlorine (Cl), bromine (Br), and iodine (I).

An emission wavelength of QDs 25 can be changed in various ways depending on, for example, a particle size and composition thereof. In the present embodiment, a fluorescence wavelength can be controlled, for example, from a green wavelength range to a red wavelength range by appropriately adjusting the particle size and composition of the QDs 25. Note that, in the disclosure, “fluorescence peak wavelength” and “emission peak wavelength” are abbreviated as “fluorescence wavelength” and “emission wavelength”, respectively. In the disclosure, the fluorescence wavelength for green light emission is preferably from 500 nm to 560 nm, more preferably from 510 nm to 550 nm, and even more preferably from 520 nm to 540 nm or less. The fluorescence wavelength for red light emission is preferably from 600 nm to 660 nm, more preferably from 610 nm to 650 nm, and even more preferably from 620 nm to 640 nm.

As described above, in the present embodiment, the fluorescence wavelength can be adjusted within a range from 500 nm to 700 nm. Thus, according to the present embodiment, it is possible to provide the light-emitting element 1 that emits light in, for example, the green wavelength range to the red wavelength range.

In the present embodiment, the particle size of the QDs 25 is preferably 2 nm or more, more preferably 3 nm or more, and even more preferably 4 nm or more. On the other hand, the particle size of the QDs 25 is preferably 20 nm or less, more preferably 15 nm or less, and even more preferably 10 nm or less. When the QDs 25 have a core-shell structure, the particle size of the core 25a and the layer thickness of the shell 25b are not limited.

The QD layer 15 is preferably formed to have a layer thickness of 20 nm or less, more preferably 10 nm or less. Thus, the light-emitting element 1 that can obtain favorable light-emission characteristics can be provided. The number of overlapping layers of the QDs 25 in the QD layer 15 is, for example, from 1 to 10 layers. Therefore, the lower limit of the layer thickness of the QD layer 15 is substantially equal to the particle size of the QDs 25. Thus, the layer thickness of the QD layer 15 is preferably 2 nm or more, for example.

The QDs 25 according to the present embodiment exhibit fluorescence characteristics with a fluorescence full-width at half-maximum of 40 nm or less and a fluorescence quantum yield percentage of 70% or more. Thus, according to the present embodiment, it is possible to provide the light-emitting element 1 containing Cd-free QDs 25 having a narrow fluorescence full-width at half-maximum and high fluorescence quantum yield in the green wavelength range to the red wavelength range.

Here, the term “fluorescence full-width at half-maximum” is a full-width at half-maximum, which indicates the spread of the fluorescence wavelength at half the intensity of a peak value of a fluorescence intensity in a fluorescent spectrum. The fluorescence quantum yield refers to the maximum fluorescence quantum yield.

In the present embodiment, the fluorescence full-width at half-maximum of the QDs 25 is preferably 35 nm or less. The fluorescence full-width at half-maximum of the QDs 25 is more preferably 30 nm or less. The fluorescence full-width at half-maximum of the QDs 25 is even more preferably 25 nm or less. According to the present embodiment, the fluorescence full-width at half-maximum of the QDs 25 can be narrowed in this manner, and thus a wide color gamut can be achieved.

The fluorescence quantum yield percentage of the QDs 25 is more preferably 80% or more, and even more preferably 90% or more. Thus, according to the present embodiment, the fluorescence quantum yield of the QDs 25 can be increased.

In general, chalcopyrite is a material that emits defect light having a fluorescence full-width at half-maximum of 70 to 100 nm. On the other hand, the QDs 25 according to the present embodiment have a narrow fluorescence full-width at half-maximum, high fluorescence quantum yield, which allows a fluorescence lifetime to be much shorter than that of the defect emission. From such characteristics, the QDs 25 according to the present embodiment are presumed to emit band-edge light.

According to the present embodiment, by using such QDs 25 in the QD layer 15, the light-emitting element 1 having excellent light-emission characteristics can be obtained.

In the light-emitting element 1, a forward voltage is applied between the anode electrode 12 and the cathode electrode 17. In other words, the anode electrode 12 is set to a higher potential than the cathode electrode 17. Through this, (i) electrons can be supplied from the cathode electrode 17 to the QD layer 15, and (ii) positive holes can be supplied from the anode electrode 12 to the QD layer 15. As a result, the QD layer 15 can generate light L with a recombination of the positive holes and the electrons. The above-described application of voltage may be controlled by a TFT (not illustrated). As an example, a TFT layer including a plurality of TFTs may be formed in the substrate 11.

Note that the light-emitting element 1 may include, as a function layer, a hole-blocking layer (HBL) that suppresses the transport of positive holes. The hole-blocking layer is, as an example, provided between the cathode electrode 17 and the QD layer 15. By providing the hole-blocking layer, the balance of the carriers (that is, positive holes and electrons) supplied to the QD layer 15 can be adjusted.

In addition, the light-emitting element 1 may include, as a function layer, an electron-blocking layer (EBL) that suppresses the transport of electrons. The electron-blocking layer is, as an example, provided between the QD layer 15 and the cathode electrode 17. By providing the electron-blocking layer, the balance of the carriers (that is, positive holes and electrons) supplied to the QD layer 15 can be adjusted.

The light-emitting element 1 may be provided with a sealing member by being sealed after film formation up to the cathode electrode 17 has been completed. For example, a glass or a plastic can be used as a sealing member. The sealing member desirably has, for example, a recessed space so that a layered body from the substrate 11 to the cathode electrode 17 can be sealed. For example, after a sealing adhesive (for example, an epoxy-based adhesive) is applied between the sealing member and the substrate 11, sealing is implemented in a nitrogen (N₂) atmosphere, and whereby the light-emitting element 1 is manufactured.

The light-emitting element 1 may have a configuration in which the cathode electrode 17, the ETL 16, the QD layer 15, the HTL 14, the HIL 13, and the anode electrode 12 are layered on the substrate 11 in this order. When the light-emitting element 1 includes the ETL 16 as described above, the light-emitting element 1 may include an electron injection layer (EIL) between the ETL 16 and the cathode electrode 17.

### Method for Manufacturing Light-Emitting Element 1

Next, a method for manufacturing the light-emitting element 1 will be described.

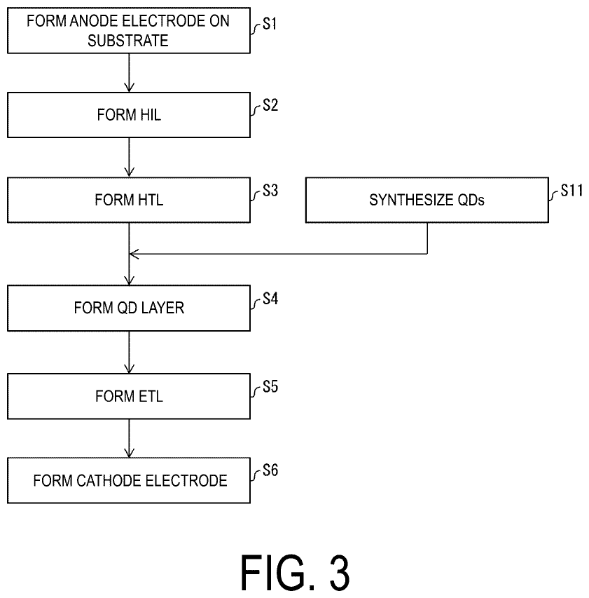

FIG. 3 is a flowchart illustrating an example of an overview of the method for manufacturing the light-emitting element 1 according to the present embodiment.

As illustrated in FIG. 3, in a manufacturing process of the light-emitting element 1 according to the present embodiment, as an example, for example, the anode electrode 12 is first formed on the substrate 11 (step S1: anode electrode forming step). Subsequently, the HIL 13 is formed on the anode electrode 12 (step S2: HIL forming step). Subsequently, the HTL 14 is formed on the HIL 13 (step S3: HTL forming step). Subsequently, the QD layer 15 is formed on the HTL 14 (step S₄: QD layer forming step). Subsequently, the ETL 16 is formed on the QD layer 15 (step S5: ETL forming step). Subsequently, the cathode electrode 17 is formed on the ETL 16 (step S6: cathode electrode forming step). Note that after formation of the cathode electrode 17 in step S6, the layered body (from the anode electrode 12 to the cathode electrode 17) formed on the substrate 11 may be sealed with a sealing member.

For example, physical vapor deposition (PVD) such as a sputtering method or a vacuum vapor deposition technique, a spin coating method, or an ink-jet method is used for formation of the anode electrode 12 in step S1 and formation of the cathode electrode 17 in step S6.

A mask (not illustrated) may be used to form the anode 12 or the cathode 17. Alternatively, each electrode material may be formed into a solid-like film by the method described above and then patterned into a desired shape as necessary.

When the light-emitting element 1 is, for example, a part of a display device, the lower layer electrode is patterned in an island shape for each light emitting element (i.e., for each pixel) as a patterned electrode. On the other hand, the upper layer electrode is, as a common electrode common to all the light-emitting elements (i.e., all pixels), formed across all pixels. Accordingly, when the light-emitting element 1 illustrated in FIG. 2 is, for example, a part of a display device, the anode electrode 12 may be formed for each pixel by forming the anode electrode material (electrode material) into a solid-like film and then patterning the film.

For example, PVD such as a sputtering method or a vacuum vapor deposition technique, a spin coating method, or an ink-jet method is used for formation of the HIL 13 in step S2 and formation (film formation) of the HTL 14 in step S3. Note that, as described above, in a case where positive holes can be sufficiently supplied to the QD layer 15 only by the HTL 14, the HIL 13 need not be provided.

For the formation (film formation) of the ETL 16 in step S5, when the ETL 16 is made of an organic material, a vacuum vapor deposition technique, a spin coating method, an ink-jet method, or the like is preferably used. When the ETL 16 is made of an inorganic material, for example, PVD such as a sputtering method or a vacuum vapor deposition technique, a spin coating method, or an ink-jet method is used for formation (film formation) of the ETL 16.

When the light-emitting element 1 is, for example, a part of a display device, among the function layers provided between the anode electrode 12 and the cathode electrode 17, the function layers other than the QD layer 15 may be formed in island shapes for the respective light-emitting elements (i.e., for pixels), or may be formed across all pixels as a common layer common to all light-emitting elements (i.e., all pixels).

Therefore, when the HIL 13, the HTL 14, and the ETL 16 are patterned in island shapes, masks (not illustrated) may be used to form the HIL 13, the HTL 14, and the ETL 16, or the respective materials may be formed into solid-like films by the method described above and then patterned into desired shapes as necessary.

A solution method is used to form the QD layer 15 in step S₄. Formation of the QD layer 15 by the solution method is performed as follows.

First, a QD dispersion containing the QDs 25 and a solvent is applied to an upper surface of an underlayer (the HTL 14 in the present embodiment). Thus, a coating film containing QDs 25 is formed. Thereafter, the solvent is volatilized to remove. Thus, the QD layer 15 can be formed by solidifying the coating film.

As the solvent described above, an organic solvent such as hexane or toluene can be used. A method of applying the QD dispersion is not limited, and may be any method such as a spin coating method, a bar coating method, or a spraying method. The QD dispersion preferably further contains the ligands 21 described above.

The QDs 25 used in step S₄ are manufactured (synthesized) in advance prior to performing step S₄. Therefore, as illustrated in FIG. 3, the method for manufacturing the light-emitting element 1 according to the present embodiment includes, for example, steps S1 to S6, and includes a QD synthesis step (step S11) before step S₄.

In step S11, the QDs 25 used for the QD dispersion (i.e., the QDs 25 used for forming the QD layer 15) are synthesized (manufactured).

### Method for Synthesizing QDs 25

Next, a method for synthesizing the QDs 25 in step S11 will be described.

An object of the present embodiment is to manufacture the light-emitting element 1 using the QDs 25, which exhibit band-edge emission and have an increased amount of Zn contained in the shells 25b to stabilize light-emission characteristics.

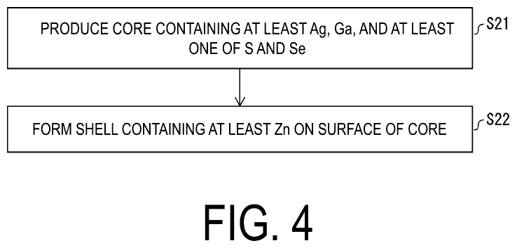

FIG. 4 is a flowchart illustrating an example of the QD synthesis step (step S11) according to the present embodiment.

In the QD synthesis step, as illustrated in FIG. 4, first, the core 25a containing at least Ag, Ga, and at least one of S and Se is produced (step S21, core producing step). Thereafter, the shell 25b containing at least Zn is formed on the surface of the cores 25a (step S22, shell forming step).

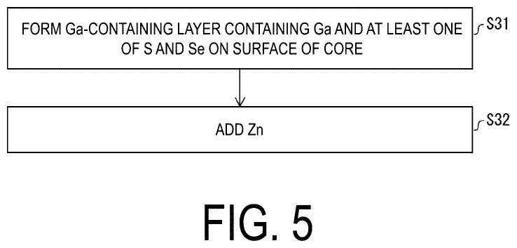

FIG. 5 is a flowchart illustrating an example of the shell forming step (step S22) according to the present embodiment.

In the shell forming step, as illustrated in FIG. 5, first, a Ga-containing layer containing Ga and at least one of S and Se is formed on the surface of the core 25a (step S31, Ga-containing layer forming step). Subsequently, Zn is added (step S32, Zn addition step).

The Ga-containing layer may contain Ga and at least one of S and Se, as described above, and may contain both S and Se. The Ga-containing layer can be denoted by, for example, a GaₓS_{w}Se_{w′}, layer (1≤x≤2, 3≤w+w′≤6, 0≤w≤6, 0≤w′≤6). Thus, the Ga-containing layer may be, for example, a GaS layer or a GaSe layer. Here, a valence of GaS in the GaS layer and a valence of GaSe in the GaSe layer are not taken into consideration. For example, GaS can be represented by GaₓS_{y} (1≤x≤2, 3≤y≤6), for example, Ga₂S₃. For example, GaSe can be represented by GaₓSe_{y′} (1≤x≤2, 3≤y′≤6), for example, Ga₂Se₃.

Further, “addition of Zn” means addition of a Zn raw material as a Zn source. “Addition of Zn” may include addition of at least one selected from the group consisting of Zn alone, ZnS, ZnSe, ZnGa₂Se₄, and ZnGa₂S₄.

According to the present embodiment, the amount of Zn in the shell 25b on the surface of the core 25a can be increased by the above method.

In step S21, as the core 25a, it is more desirable to produce the core 25a containing Ag, Ga, and S, or Ag, Ga, and Se, and it is particularly desirable to produce the core 25a containing Ag, Ga, and Se. That is, the core 25a is more preferably made of AgGaS or AgGaSe, and particularly preferably made of AgGaSe.

In step S32, by adding Zn after the formation of the Ga-containing layer as described above, a Zn-containing layer containing Zn and at least one of S and Se can be formed.

The Zn-containing layer may contain Zn and at least one of S and Se, as described above, and may contain both S and Se. The Zn-containing layer can be denoted as, for example, a ZnSₜSe₁₋ₜ layer (0≤t≤1). Thus, the Zn-containing layer may be, for example, a ZnS layer or a ZnSe layer.

In step S31, the Ga-containing layer may cover the core 25a. In step S32, the Zn-containing layer may cover the Ga-containing layer.

Thus, in the present embodiment, the surface of the core 25a may be covered with the Ga-containing layer and then covered with the Zn-containing layer. To be specific, for example, the surface of the core 25a may be covered with GaS (i.e., GaₓS_{y}, 1≤x≤2, 3≤y≤6) and then covered with ZnS.

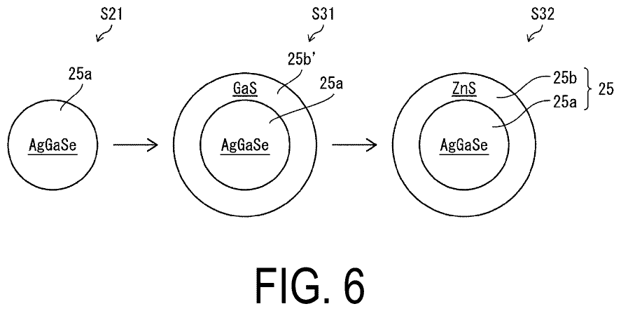

FIG. 6 is a conceptual view illustrating an example of a manufacturing process of the QD 25 according to the present embodiment.

In the example illustrated in FIG. 6, as an example, the core 25a (AgGaSe core) made of AgGaSe is produced in step S21 as illustrated in a left diagram in FIG. 6. Thereafter, as illustrated in a middle diagram in FIG. 6, the surface of the AgGaSe core is covered with the GaS shell as an initial shell layer 25b′ in step S31. Thereafter, as illustrated in a right diagram in FIG. 6, Zn is post-added in step S32 to obtain a ZnS shell as the shell 25b. As illustrated in the middle diagram in FIG. 6, the GaS shell covering the surface of the AgGaSe core is an important shell for preventing Zn from diffusing into the core 25a when adding Zn in step S32. In the example illustrated in FIG. 6, after the addition of Zn, for example, Ga escapes from the shell 25b to the outside through dissolution and a washing step, so that the QD 25 with the ZnS shell formed on the surface of the AgGaSe core can be obtained.

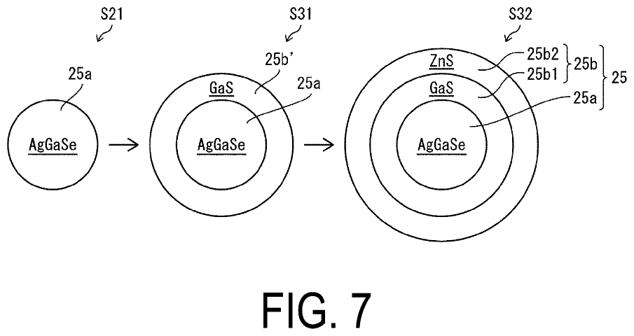

FIG. 7 is a conceptual diagram illustrating another example of a manufacturing process of the QD 25 according to the present embodiment.

As described above, after the addition of Zn, it is considered that an amount of Ga remaining in the shell 25b decreases as, for example, Ga escapes from the shell 25b to the outside through the dissolution and the washing step. However, as illustrated in FIG. 7, Ga remaining without escaping to the outside in the dissolution and the washing step may be contained in the shell 25b.

For example, after covering the surface of the AgGaSe core with the GaS shell as the initial shell layer 25b′, the GaS shell may be interposed between the AgGaSe core and the ZnS shell by post-adding Zn in step S32 as illustrated in a right diagram in FIG. 7. In this case, as illustrated in the right diagram in FIG. 7, for example, the shell 25b may have a dual-layer structure of a first shell layer 25b1 (innermost layer) made of GaS and a second shell layer 25b2 (outermost layer) made of ZnS.

Although not illustrated, in FIG. 6, the shell 25b may be a ZnGa₂S₄ layer instead of the ZnS layer. In FIG. 7, due to diffusion of Zn and movement of Ga in the dissolution and the washing step, one of the first shell layer 25b1 (innermost layer) and the second shell layer 25b2 (outermost layer) may be a ZnGa₂S₄ layer. However, as will be described later, the present embodiment is not limited to this.

According to study by the inventors of the present application, for example, even when the surface of the AgGaSe core is covered with a layer containing at least one of S and Se but not containing Ga as the initial shell layer 25b′ and then covered with, for example, a ZnS layer by adding Zn, Zn immediately diffuses to the inside of the core 25a, resulting in defect emission. Thus, when the initial shell layer 25b′ does not contain Ga, a large amount of ZnS covering cannot be performed. On the other hand, in the present embodiment, for example, crystallinity of ZnS obtained by post-addition of Zn after GaS covering, was confirmed.

When covering the core 25a with the shell 25b (hereinafter, simply referred to as “when covering with the shell”), for example, oleylamine is generally used as a solvent. However, oleylamine is considered to be ligands that prevent covering of the core 25a with the shell. In fact, it has been found that GaS covering operation without a shift in an X-ray diffraction spectrum (XRD spectrum) leads to defect emission immediately upon the addition of Zn.

On the other hand, in the present embodiment, for example, dodecanethiol (DDT), which is not amine-based, is used as a solvent when covering with the shell. Other than DDT, octadecene (ODE) can also be used. However, oleylamine can also be contained when it is not a main solvent. As shown in the experimental results to be described later, the XRD spectrum shifts during the GaS covering stage after the use of DDT. Thus, in the present embodiment, by covering the core 25a with GaS using DDT (or ODE) as a solvent, the core 25a can be covered without Ag diffusing to the shell 25b on the surface of the core 25a.

According to the method for manufacturing the QD 25 according to the present embodiment, diffusion of Ag contained in the core 25a into the shell 25b can be prevented. Further, when Se is contained in the core 25a, Se in the core 25a can be appropriately separated from S contained in the shell 25b. Furthermore, according to the method for manufacturing the QD 25 according to the present embodiment, the amount of Zn contained in the shell 25b can be increased. Although not limited, according to the present embodiment, the amount of Zn in the QD 25 can be adjusted to 2 wt. % or more, preferably 5 wt. % or more, and more preferably 10 wt. % or more.

The method for manufacturing the QD 25 according to the present embodiment will be described below in more specific and in detail by taking the case of producing the AgGaSe core as described above as an example. In the present embodiment, first, a silver raw material (Ag raw material) as an Ag source, a gallium raw material (Ga raw material) as a Ga source, and a selenium raw material (Se raw material) as a Se source are heated in one pot to synthesize the core 25a.

A reaction temperature for heating when synthesizing the core 25a is set within a range from 100° C. to 320° C. The reaction temperature is preferably 280° C. or lower, which is a further lower temperature.

The Ag raw material (Ag source) may be an organic silver compound or an inorganic silver compound. The Ag raw material is not limited, and for example, silver acetate (CH₃C(═O)OAg, also known as Ag(OAc)); silver nitrate (AgNO₃); halides such as silver chloride (AgCl), silver bromide (AgBr), and silver iodide (AgI); and carbamates such as silver diethyldithiocarbamate (Ag(SC(═S)N(C₂H₅)₂)) and silver dimethyldithiocarbamate (Ag(SC(═S)N(CH₃)₂)) can be used. A single type of these Ag raw materials may be used alone, or two or more types may be mixed and used, as appropriate.

The Ag raw material may be directly added to a reaction solution, or may be dissolved in an organic solvent in advance to prepare a solution having a certain concentration, which may then be used as an Ag raw material solution.

The Ga raw material (Ge source) may be an organic gallium compound or an inorganic gallium compound. The Ga raw material is not limited, and for example, gallium acetate (Ga(OAc)₃); gallium nitrate (GaNO₃); gallium acetylacetonate (Ga(CH₃C(═O)CH═C(═O)CH₃)₃, also known as Ga(acac)₃; halides such as gallium chloride (GaCl₃), gallium bromide (GABr₃), and gallium iodide (Ga₂I₆); and carbamates such as gallium diethyldithiocarbamate (Ga[(SC(═S)N(C₂H₅)₂)₂]₃) can be used. A single type of these Ga raw materials may be used alone, or two or more types may be mixed and used, as appropriate.

The Ga raw material may be directly added to the reaction solution, or may be dissolved in an organic solvent in advance to prepare a solution having a certain concentration, which may then be used as a Ga raw material solution.

As the Se raw material (Se source), an organic selenium compound (organic chalcogen compound) can be used. The organic selenium compound (organic chalcogen compound) is not limited, and for example, trioctylphosphine selenide ((C₈H₁₇)₃P═Se) obtained by dissolving selenium in trioctylphosphine; tributylphosphine selenide ((C₄H₉)₃P═Se) obtained by dissolving selenium in tributylphosphine; a solution obtained by dissolving selenium in a high-boiling-point solvent that is a long-chain hydrocarbon such as octadecene at a high temperature; and a solution (Se-OLAm/DDT) obtained by dissolving selenium in a mixture of oleylamine and dodecanethiol can be used. A single type of these Se raw materials may be used alone, or two or more types may be mixed and used, as appropriate.

As described above, when AgGaSe is synthesized as the core 25a, the Se raw material (selenium raw material species) greatly contributes to the fluorescence characteristics. In particular, the Se-OLAm/DDT exhibits excellent light-emission characteristics. In ordinary chalcopyrite-based QD, two types of light emission can be confirmed in an early stage of light emission, a PL spectrum that is considered to be band-edge emission and a PL spectrum that is considered to be defect emission, and a light emission intensity ratio (band-edge emission)/(defect emission) is 10 or less in most cases. Then, as the reaction proceeds further, intensity of the defect emission gradually decreases, and intensity of the band-edge emission often increases accordingly. However, when Se-OLAm/DDT is used as the Se source as in the present embodiment, the light emission has a single peak from the initial stage, (band-edge emission)/(defect emission) is 10 or more, and almost no peak considered to be defect emission can be confirmed. Further, the fluorescence lifetime until 1/e is as short as 20 ns or less, and only a peak, which is not defect emission, can be confirmed in the initial stage of light emission. Thus, by using Se-OLAm/DDT as the Se source, it is possible to provide the light-emitting element 1 that can obtain more favorable light-emission characteristics.

Next, in the present embodiment, the surface of the core 25a made of nanocrystals is covered with the shell 25b. Thus, the fluorescence quantum yield can be further increased. As described above, in this example, the surface of the core 25a is first covered with GaS, and then Zn is added. Here, the Ga source is as described above.

The S raw material (S source) is not limited, and for example, an organic sulfur compound such as thiol can be used. Examples of thiol include octadecanethiol (C₁₈H₃₇SH); hexanedecanethiol (C₁₆H₃₃SH); tetradecanethiol (C₁₄H₂₉SH); dodecanethiol (C₁₂H₂₅SH); decanethiol (C₁₀H₂₁SH); and octanethiol (C₈H₁₇SH). Examples of the organic sulfur compounds other than thiol that can be used include a S-ODE raw material obtained by dissolving sulfur in octadecene (ODE); a S-DDT raw material obtained by dissolving sulfur in dodecanethiol (DDT); a disulfide-based S raw material; a thiuram-based S raw material; and S-OLAm/DDT obtained by dissolving sulfur in oleylamine (OLAm) and dodecanethiol (DDT). A single type of these S raw materials may be used alone, or two or more types may be mixed and used, as appropriate.

The Zn raw material (Zn source) may be an organic zinc compound, an inorganic zinc compound, or zinc (Zn) alone. An organic zinc compound and an inorganic zinc compound are raw materials that are stable even in air and easy to handle. These raw materials can also be used as the ligands 21. Structures of an organic zinc compound and an inorganic zinc compound are not limited, and for example, the following organic zinc compounds and inorganic zinc compounds can be used.

Examples of an organic zinc compound that can be used include zinc acetate (Zn(OAc)₂), which is an acetate; zinc nitrate (Zn(NO₃)₂); fatty acid salts such as zinc stearate (Zn(OC(═O)C₁₇H₃₅)₂), zinc oleate (Zn(OC(═O)C₁₇H₃₃)₂), zinc palmitate (Zn(OC(═O)C₁₅H₃₁)₂), zinc myristate (Zn(OC(═O)C₁₃H₂₇)₂), zinc dodecanoate (Zn(OC(═O)C₁₁H₂₃)₂), and zinc acetylacetonate (Zn(CH₃C(═O)CH═C(═O)CH₃)₂, also known as Zn(acac)₂; and zinc carbamates such as zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(═S)N(C₄H₉)₂)₂. Examples of an inorganic zinc compound that can be used include halides such as zinc chloride (ZnCl₂), zinc bromide (ZnBr₂), and zinc iodide (ZnI₂); sulfides such as ZnS and ZnGa₂S₄; and selenides such as ZnSe and ZnGa₂Se₄. A single type of these Zn raw materials may be used alone, or two or more types may be mixed and used, as appropriate.

In the present embodiment, QDs 25 can be obtained in one pot without isolating and purifying precursors.

In the above description and FIGS. 6 and 7, the case of producing the core 25a made of AgGaSe (AgGaSe core) has been described as an example. However, as the core 25a, the core 25a containing at least Ag, Ga, and S may be produced as described above. For example, as described above, instead of the AgGaSe core, the core 25a made of AgGaS (AgGaS core) may be produced. The Ag raw material, the Ga raw material, and the S raw material at this time are as described above. As described above, the core 25a can contain Cu or In.

Regarding the shell 25b, when ZnSe or ZnGa₂Se₄ is to be finally obtained by addition of Zn, the initial shell layer 25b′ formed first is preferably GaSe. Thus, when the initial shell layer 25b′ is made of GaSe, it is considered that the shell 25b containing ZnSe or ZnGa₂Se₄ or both of them can be finally obtained. However, after the core 25a is covered with GaSe, it may be covered with ZnS or ZnGaS. In this case, due to diffusion of Zn or movement of Ga in the dissolution and the washing step, it is considered possible to obtain the shell 25b including the first shell layer 25b1 containing GaSe, ZnSe, or ZnGa₂Se₄ and the second shell layer 25b2 containing ZnS, ZnGaS, or ZnGa₂S₄.

When the initial shell layer 25b′ is made of GaS, it is considered that the addition of Zn can finally provide the shell 25b containing ZnS or ZnGa₂S₄ or both of them. However, as the shell 25b, after the core 25a is covered with GaS, it may be covered with ZnSe or ZnGaSe. In this case, due to diffusion of Zn or movement of Ga in the dissolution and the washing step, it is considered possible to obtain the shell 25b including the first shell layer 25b1 containing GaS, ZnS, or ZnGa₂S₄ and the second shell layer 25b2 containing ZnSe, ZnGaSe, or ZnGa₂Se₄.

That is, in the present embodiment, as an example, after the core 25a is covered with GaS, it may be covered with ZnS or ZnGaS, or may be covered with ZnSe or ZnGaSe. Also, after the core 25a is covered with GaSe, it may be covered with ZnSe or ZnGaSe, or may be covered with ZnS or ZnGaS. Similar to the core 25a, the shell 25b may contain at least one of S and Se, and may contain both of them. At this time, as described above, when the core 25a contains one of S and Se and the shell 25b contains the other, the one of S and Se contained in the core 25a and the other of S and Se contained in the shell 25b can be appropriately separated.

Therefore, for example, when an AgGaSe core is produced as the core 25a, it is desirable to be covered with a GaS shell as the initial shell layer 25b′ as described above. In this case, as described above, it is considered that the shell 25b containing ZnS or ZnGa₂S₄ or both of them can be finally obtained. In this case, Se contained in the AgGaSe core and S contained in ZnS or ZnGa₂S₄ can be appropriately separated.

When a AgGaS core is produced as the core 25a, it is desirable to be covered with a GaSe shell as the initial shell layer 25b′ as described above. In this case, as described above, it is considered that the shell 25b containing ZnSe or ZnGa₂Se₄ or both of them can be finally obtained. In this case, S contained in the AgGaS core and Se contained in ZnSe or ZnGa₂Se₄ can be appropriately separated.

In the method for manufacturing the QD 25 according to the present embodiment, as described above, after the core 25a is formed, a predetermined element is post-added to synthesize the shell 25b. At this time, In may be contained in the initial stage of the reaction for producing the core 25a, but it is preferable not to contain In. This makes it possible to obtain favorable light-emission characteristics.

In addition, in the present embodiment, when the QD 25 contains Zn, it is preferable to add Zn by paying attention to the following points. First, Zn is preferably added in the final step rather than during the initial reaction. This is because when Zn is contained inside a QD particle (to be specific, in the core 25a), defect emission may be dominant or only defect emission may be confirmed. Therefore, the purpose of adding Zn in the final step is to allow Zn to react only with the surface of the QD particle. Second, Zn is preferably added at a low temperature. Here, “low temperature” means about 150 to 250° C. When the temperature upon adding Zn is high, Zn diffuses into the internal QD of the QD particle (to be specific, in the core 25a) and reacts, thereby facilitating defect emission. Therefore, in order to limit the reaction between the QD particle and Zn to the surface of the QD particle, Zn is preferably allowed to react only with the surface of the QD particle at a low temperature.

In the present embodiment, gallium acetylacetonate (Ga(acac)₃) is preferably used as a Ga raw material when synthesizing AgGaSe. By using gallium acetylacetonate as the Ga raw material, more favorable light-emission characteristics can be obtained than when gallium chloride is used as the Ga raw material, for example.

The Se raw material is preferably Se-OLAm/DDT. Thus, defect emission can be effectively prevented.

In the present embodiment, the QDs 25 having a core-shell structure are formed and then purified using a specific solvent. For example, trioctylphosphine (TOP) can be used as the solvent, but high fluorescence quantum yield can be obtained even when TOP is not contained. TOP may also be included as the ligands 21. Further, in the present embodiment, the synthesized reaction solution may be centrifuged. By centrifuging the reaction solution obtained by the synthesis to remove aggregates, QDs 25 having more excellent light-emission characteristics can be obtained.

In centrifugation, large and small particles are separated. In the present embodiment, centrifugation is performed by adding solvents such as toluene and ethanol. Thus, even when the particle sizes of the QDs 25 are uniform, by controlling a ratio of solvents such as toluene and ethanol, an aggregation state of the QDs 25 can be changed depending on, for example, types and amounts of the ligands 21 coordinated to the surfaces of the QDs 25. At this time, the ratio can be controlled within a range of (QDs 25):toluene:ethanol=1:(0.5 to 2):(0.5 to 2). Methanol may be used in place of ethanol. As a result, QDs 25 having high fluorescence quantum yield and QDs 25 having low fluorescence quantum yield can be separated. Thereafter, by adding trioctylphosphine (TOP), which serves as the ligands 21, as a solvent to the separated QDs 25, the fluorescence quantum yield can be further improved. However, the addition of TOP is not essential.

As described above, according to the method for manufacturing the QDs 25 according to the present embodiment, the surface of the core 25a containing at least Ag, Ga, and at least one of S and Se can be appropriately covered with the shell 25b containing a large amount of Zn. Thus, the QDs 25 having band-edge emission with a fluorescence full-width at half-maximum of 40 nm or less can be manufactured with high accuracy, enabling mass production of the QDs 25 and thus mass production of the light-emitting element 1. In addition, according to the method for manufacturing the QDs 25 according to the present embodiment, it is possible to contain a large amount of Zn on the surfaces of the QDs 25 while maintaining band-edge emission. In the present embodiment, the core 25a can be appropriately covered with the shell 25b containing Zn (e.g., the shell 25b including a ZnS shell). According to the present embodiment, the surface of the core 25a can be appropriately covered with the shell 25b containing a large amount of Zn as described above, thus improving stability of the fluorescence characteristics and obtaining high fluorescence quantum yield, specifically, a fluorescence quantum yield percentage of 70% or more.

Next, the advantageous effects of the QDs 25 and the light-emitting element 1 according to the present embodiment will be described with reference to synthesis examples, examples of QDs 25, and a comparative example. Note that the QDs 25 and the light-emitting element 1 according to the present embodiment are not limited to the following synthesis examples and examples.

Note that raw materials and measuring instruments used in the following synthesis examples, examples, and comparative example are as follows.

Solvent Oleylamine (OLAm) available from Kao Corporation was used as OLAm.

Dodecanethiol (DDT) available from Kao Corporation was used as DDT. Toluene available from DAISHIN CHEMICAL CO., LTD was used as toluene. Ethanol available from DAISHIN CHEMICAL CO., LTD was used as ethanol. “Lunac O-V” available from Kao Corporation was used as oleic acid (OLAc). Octadecene (ODE) available from Idemitsu Kosan Co., Ltd. was used as ODE.

### Ag Raw Material

Silver acetate (Ag(OAc)) available from Aldrich Co., Ltd. was used as Ag(OAc). Ag(OAc)—OLAm solution (concentration 0.2 M) was prepared by dissolving silver acetate (Ag(OAc)) in oleylamine (OLAm).

### Ga Raw Material

Gallium acetylacetonate (Ga(acac)₃) available from Tokyo Chemical Industry Co., Ltd. was used as Ga(acac)₃. Ga(acac)₃-OLOH(Ga(acac)₃-OLOH solution (concentration 0.1 M) was prepared by dissolving gallium acetylacetonate (Ga(acac)₃) in oleyl alcohol (OLOH). Gallium chloride (GaCl₃) available from Shinko Chemical Co., Ltd. was used as GaCl₃. GaCl₃—OLAc/ODE (concentration 0.1 M) was prepared by dissolving gallium chloride (GaCl₃) in a mixed solvent of oleic acid (OLAc) and octadecene (ODE). Volume ratio of OLAc:ODE in GaCl₃—OLAc/ODE was 1:21.

### Se Raw Material

Se-OLAm/DDT (Se-OLAm/DDT solution) (concentration 0.7 M) was prepared by dissolving selenium (Se) in a mixed solvent of oleylamine (OLAm) and dodecanethiol (DDT). Volume ratio of OLAm:DDT in Se-OLAm/DDT was 5:2. Selenium (Se) available from Shinko Chemical Co., Ltd. was used as Se.

### Zn Raw Material

ZnBr₂-DDT (ZnBr₂-DDT solution) (concentration 0.2 M) was prepared by dissolving zinc bromide (ZnBr₂) in dodecanethiol (DDT). Zinc bromide (ZnBr₂) available from Kishida Chemical Co., Ltd. was used as ZnBr₂.

### S Raw Material

S-DDT (S-DDT solution) (concentration 0.4 M) was prepared by dissolving sulfur (S) powder in dodecanethiol (DDT). S-ODE (concentration 0.2 M) was prepared by dissolving sulfur (S) powder in octadecene (ODE). Sulfur (S) available from Kishida Chemical Co., Ltd. was used as S.

### Measuring Instrument

“F-2700” available from JASCO Corporation was used as a fluorescence spectrometer. “QE-1100” available from Otsuka Electronics Co., Ltd. was used as a quantum yield measuring device. The scanning electron microscope (SEM) function of “SU9000” available from Hitachi, Ltd. was used as the SEM. “D2 PHASER” available from Bruker Corporation was used as an X-ray diffraction (XRD) device. “JEM-ARM200CF” available from JEOL Ltd. was used as the transmission electron microscope (TEM). “JED 2300T” available from JEOL Ltd. was used as an energy dispersive X-ray (EDX) analyzer. The scanning transmission electron microscope (STEM) function of “SU9000” available from Hitachi, Ltd. was used as the STEM. A light-emitting diode (LED) measuring device available from Spectra Co-op (two-dimensional CCD small high sensitivity spectrometer: “Solid Lambda CCD” available from Carl Zeiss AG) was used as the LED measurement device.

First, synthesis examples of the QDs 25 according to the present embodiment will be described.

### Synthesis Example 1 of QDs 25

In Synthesis Example 1, the QDs 25 were produced through the production process illustrated in FIG. 6.

To be specific, first, in order to produce the cores 25a, a 100 mL reaction vessel was charged with 0.5 mL of the Ag(OAc)-OLAm (concentration 0.2 M), 36.7 mg of gallium acetylacetonate (Ga(acac)₃), 20.0 mL of oleylamine (OLAm), and 2.0 mL of dodecanethiol (DDT). In an inert gas (N₂) atmosphere, the raw materials in the reaction vessel were then dissolved by heating at 150° C. for 10 minutes while stirring to obtain a solution.

Subsequently, 0.3 mL of the Se-OLAm/DDT was added from above to the solution in the reaction vessel. Thereafter, the solution in the reaction vessel was heated from 150° C. to 320° C. and stirred for a total of 10 minutes. A resulting reaction solution (1A) was then cooled to room temperature.

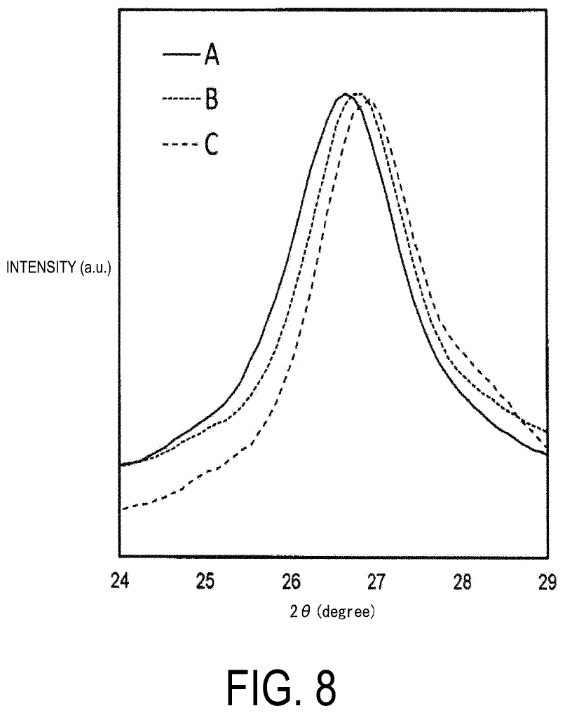

Subsequently, the reaction solution (1A) was centrifuged at 5500 rpm for 3 minutes to obtain a precipitate (1B). The precipitate (1B) was re-dispersed in toluene, added with ethanol, and then centrifuged at 7500 rpm for 3 minutes to obtain a precipitate (IC) to be the cores 25a of the QDs 25 according to Synthesis Example 1. Thereafter, the precipitate (IC) was re-dispersed in 10.0 mL of dodecanethiol (DDT) to obtain a dispersion (1D). On the other hand, part of the precipitate (IC) was taken as Sample A, and Sample A was subjected to X-ray diffraction measurement using the XRD device. This result is shown as A in FIG. 8.

Subsequently, the shells 25b were formed. In this step, a 100 mL reaction vessel was charged with the dispersion (1D) and heated at 270° C. for 10 minutes in an inert gas (N₂) atmosphere. Thereafter, 0.15 mL of the S-DDT (concentration 0.4 M) and 0.2 mL of the Ga(acac)₃-OLOH (concentration 0.1 M) were each alternately dropped five times every 10 minutes. A resulting reaction solution (1E) was then cooled to room temperature.

Subsequently, toluene and ethanol were added to the reaction solution (1E) cooled to room temperature, and then a mixture was centrifuged at 7500 rpm for 3 minutes to obtain a precipitate (1F) in which each of the cores 25a was covered with a GaS shell as the initial shell layer 25b′. Thereafter, the precipitate (1F) was re-dispersed in 10.0 mL of dodecanethiol (DDT) to obtain a dispersion (1G). On the other hand, part of the precipitate (1F) was taken as Sample B, and Sample B was subjected to X-ray diffraction measurement using the XRD device. This result is shown as B in FIG. 8.

Subsequently, a 100 mL reaction vessel was charged with the dispersion (1G) and heated at 180° C. for 10 minutes in an inert gas (N₂) atmosphere. Thereafter, 0.1 mL of the ZnBr₂-DDT (concentration 0.2 M) and 0.1 mL of the S-DDT (concentration 0.4 M) were each alternately dropped five times every 10 minutes. A resulting reaction solution was then cooled to room temperature to obtain a QD dispersed solution (1H) containing the QDs 25 according to Synthesis Example 1, in each of which the core 25a was covered with the shell 25b.

Subsequently, a fluorescence wavelength and a fluorescence full-width at half-maximum of the QDs 25 in the QD dispersed solution (1H) were measured with the fluorescence spectrometer, and fluorescence quantum yield of the QDs 25 in the QD dispersed solution (1H) was measured with the quantum yield measuring device.

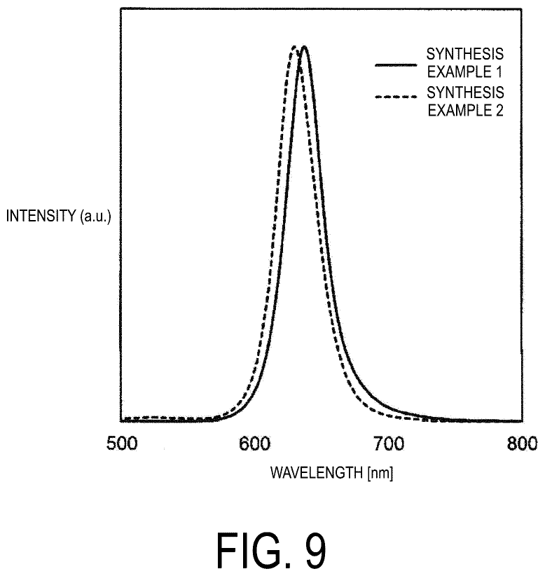

As shown in FIG. 9, the measurement results indicated optical characteristics including the fluorescence wavelength of 637.5 nm, the fluorescence full-width at half-maximum of 32.11 nm, and the fluorescence quantum yield percentage of 76%.

In addition, toluene and ethanol were added to the QD dispersed solution (1H), and then a mixture was centrifuged at 7500 rpm for 3 minutes to obtain a precipitate (1I). Thereafter, part of the precipitate (1I) was taken as Sample C, and Sample C was subjected to X-ray diffraction measurement using the XRD device. This result is shown as C in FIG. 8.

Results of Analysis by X-Ray Diffraction (XRD) Device FIG. 8 shows XRD spectra of Samples A to C obtained in the respective synthesis stages of Synthesis Example 1. Here, Sample A (precipitate IC) is AgGaSe₂ particles obtained as the cores 25a. Sample B (1F) is particles (AgGaSe₂/GaS particles) obtained by adding Ga and S to the cores 25a.

From the XRD spectra of Sample A and Sample B shown in FIG. 8, it was confirmed that an XRD maximum peak of Sample B is shifted to a high angle side with respect to an XRD maximum peak of Sample A by forming GaS as the initial shell layers 25b′ as described above.

Sample C is QDs 25 according to the present embodiment having the shells 25b containing Zn and S obtained by adding Zn and S to the AgGaSe₂/GaS particles.

From the XRD spectra of Sample B and Sample C shown in FIG. 8, it was confirmed that an XRD maximum peak of Sample C was shifted to a high angle side with respect to the XRD maximum peak of Sample B by post-addition of Zn as described above.

From such shifts of the XRD maximum peak, it can be presumed that Ag contained in the core 25a does not diffuse into the shell 25b, and the core 25a is covered with the shell 25b containing a large amount of Zn.

### Results of Analysis by TEM-EDX

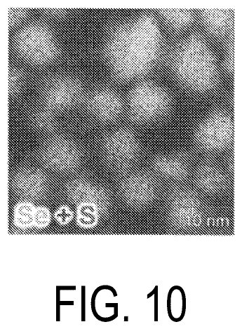

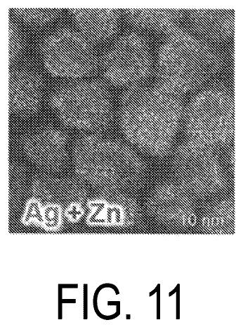

TEM-EDX observation images of the QDs 25 obtained in Synthesis Example 1, which were analyzed using the TEM and the EDX analyzer are shown in FIGS. 10 and 11. FIG. 10 is a TEM-EDX observation image of Se+S in the QDs 25. FIG. 11 is a TEM-EDX observation image of Ag+Zn in the QDs 25. From the observation image shown in FIG. 10, it was found that Se and S were separately present in the QD 25, and to be specific, S was present around Se. In addition, it was found that Ag and Zn were separately present in the QD 25, and to be specific, Zn was present around Ag. From the observation image shown in FIG. 11, Se and Ag are mainly contained in the core 25a, and S and Zn are mainly contained in the shell 25b. According to Synthesis Example 1, it was found that the components contained in the core 25a were able to be prevented from diffusing into the shell 25b and the components contained in the shell 25b were able to be prevented from diffusing into the core 25a.

### Synthesis Example 2 of QDs 25

In this synthesis example, the same operations as in Synthesis Example 1 were carried out up to covering with the GaS shells to obtain a dispersion (2G) similar to the dispersion (1G) and containing a precipitate (2F) similar to the precipitate (1F).

Subsequently, a 100 mL reaction vessel was charged with the dispersion (2G) and heated at 180° C. for 10 minutes in an inert gas (N₂) atmosphere. Thereafter, 0.1 mL of the ZnBr₂-DDT (concentration 0.2 M) and 0.1 mL of the S-DDT (concentration 0.4 M) were each alternately dropped five times every 10 minutes. A resulting reaction solution (2H) was then cooled to room temperature (Zn addition step).

Subsequently, toluene and ethanol were added to the reaction solution (2H) cooled to room temperature, and then a mixture was centrifuged at 7500 rpm for 3 minutes to obtain a precipitate (2I). Thereafter, the precipitate (2I) was re-dispersed in 10.0 mL of dodecanethiol (DDT) to obtain a dispersion (2J) (washing step).

In Synthesis Example 2, after obtaining the dispersion (2G), the Zn addition step and the washing step performed until the dispersion (2J) was obtained were regarded as one set, and repeated eight times (i.e., eight sets), and then the Zn addition step was performed again. That is, in Synthesis Example 2, the set of the Zn addition step and the washing step was repeated nine times without the washing step in a final set.

After obtaining the dispersion (2G) and performing the Zn addition step nine times in total (i.e., after the ninth set of Zn addition step), a resulting reaction solution was cooled to room temperature. Thus, a QD dispersed solution (2K) containing the QDs 25 according to Synthesis Example 2 was obtained.

Subsequently, a fluorescence wavelength and a fluorescence full-width at half-maximum of the QDs 25 in the QD dispersed solution (2K) were measured with the fluorescence spectrometer, and fluorescence quantum yield of the QDs 25 in the QD dispersed solution (2K) was measured with the quantum yield measuring device.

As shown in FIG. 9, the measurement results indicated optical characteristics including the fluorescence wavelength of 630 nm, the fluorescence full-width at half-maximum of 34 nm, and the fluorescence quantum yield percentage of 94%.

Results from High-Resolution STEM

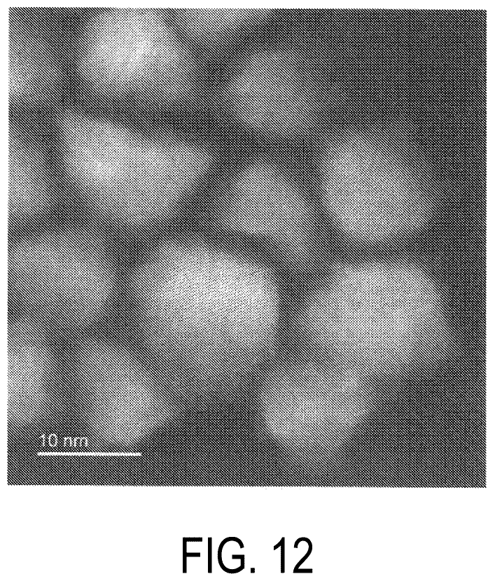

FIG. 12 shows a STEM image obtained by analyzing the QDs 25 obtained in Synthesis Example 2 using the STEM as a high-resolution STEM. The particles shown in FIG. 12 was confirmed, and crystal lattices were observed from the entire particles. From this result, it can be presumed that the shells 25b are crystallized, so it is considered that the diffusion of Ag contained in the cores 25a and the diffusion of Zn contained in the shells 25b are prevented.

### Results of Analysis by TEM-EDX

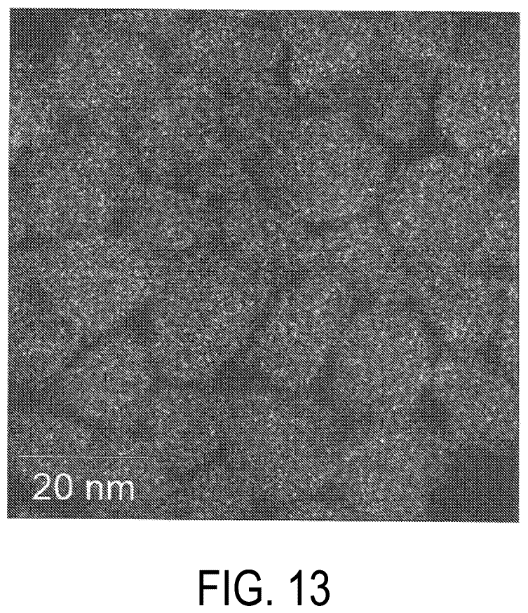

TEM-EDX observation image of the QDs 25 obtained in Synthesis Example 2, which was analyzed using the TEM and the EDX analyzer, is shown in FIG. 13. The observation image in FIG. 13 is a TEM-EDX observation image of Ag+Zn in the QDs 25. From the observation image shown in FIG. 13, it was found that Zn was present around Ag, so that the diffusion of the components contained in the core 25a into the shell 25b is prevented, and the diffusion of the components contained in the shell 25b into the core 25a is also prevented.

### Comparative Example

In this comparative example, 0.2 mL of GaCl₃—OLAc/ODE (concentration 0.1 M) was used as the Ga raw material in place of 0.2 mL of the Ga(acac)₃-OLOH (concentration 0.1 M) in the step of forming the shell 25b in Synthesis Example 1. In the step of forming the shell 25b in Synthesis Example 1, 0.15 mL of S-ODE (concentration 0.2 M) was used as the S raw material in place of 0.15 mL of S-DDT (concentration 0.4 M). Except for these points, a QD dispersed solution (1H′) containing QDs for comparison according to this comparative example was obtained by performing operations similar to the manufacturing operations in Synthesis Example 1.

### Results of Measurement of Zn Content

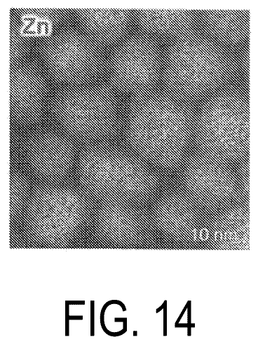

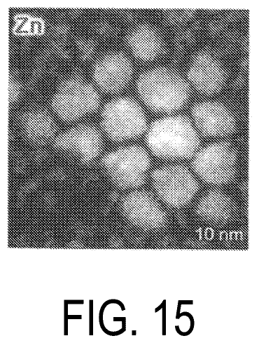

FIG. 14 shows a TEM-EDX observation image of Zn in the QDs 25 obtained by analyzing the QDs 25 obtained in Synthesis Example 1 using the TEM and the EDX analyzer. FIG. 15 shows a TEM-EDX observation image of Zn in the QDs obtained by analyzing the QDs for comparison obtained in this comparative example using the TEM and the EDX analyzer.

From the experimental results shown in FIGS. 14 and 15, the QDs 25 obtained in Synthesis Example 1 contained a larger amount of Zn on the surfaces of the cores than the QDs for comparison obtained in this comparative example, confirming the surface of AgGaSe was able to be appropriately covered with GaS and ZnS.

In addition, the amount of Zn contained in each of the QD for comparison obtained in Comparative Example and the QDs 25 obtained in Synthesis Example 1 and Synthesis Example 2 was measured with the EDX analyzer. As a result, the amount of Zn contained was about 1 wt. % in the QD for comparison, about 5 wt. % in the QD 25 of Synthesis Example 1, and about 10 wt. % in the QD 25 of Synthesis Example 2. From the analysis results by the X-ray diffraction (XRD), the analysis results by the TEM-EDX, and the results from the high-resolution STEM described above, in the QDs 25 obtained in Synthesis Examples 1 and 2, diffusion of Zn contained in the shell 25b into the core 25a is prevented. Therefore, the amount of Zn contained in the QD 25 can be regarded as the amount of Zn contained in the shell 25b of the QD 25.

This indicates that according to Synthesis Example 1 and Synthesis Example 2, the amount of Zn contained in the QD, more specifically, the amount of Zn contained in the shell of the QD can be increased from several times to about 10 times as compared with Comparative Example. In addition, the amount of Zn contained in the QD 25 in Synthesis Example 2 was about twice as large as the amount of Zn contained in the QD 25 in Synthesis Example 1. This is because the number of post-addition steps of Zn was increased in Synthesis Example 2.

### Example 1

In Example 1, except that in Synthesis Example 2, after obtaining the dispersion (2G), the set of the Zn addition step and the washing step was repeated twice (i.e., two sets) and then the Zn addition step was performed again, a QD dispersed solution (3K) containing QDs 25 according to Example 1 was obtained by performing operations similar to the manufacturing operations in Synthesis Example 2. That is, in this example, in Synthesis Example 2, the set of the Zn addition step and the washing step was repeated three times without performing the washing step in the final set. Thereby, after obtaining the dispersion (2G) and then performing the Zn addition step three times in total (i.e., after the third set of Zn addition step), a resulting reaction solution was cooled to room temperature to obtain the QD dispersed solution (3K) containing QDs 25 according to Example 1.

Using this QD dispersion (3K), three types of light-emitting elements 1 having the following layered structures were manufactured as Samples (1) to (3).
Sample (1): ITO (30 nm)/PEDOT:PSS (40 nm)/PVK (20 nm)/QD layer (14 nm)/ZnO (65 nm)/Al (65 nm)
Sample (2): ITO (30 nm)/PEDOT:PSS (40 nm)/PVK (20 nm)/QD layer (19 nm)/ZnO (65 nm)/Al (65 nm)
Sample (3): ITO (30 nm)/PEDOT:PSS (40 nm)/PVK (20 nm)/QD layer (31 nm)/ZnO (65 nm)/Al (65 nm)

Specifically, first, the anode electrode 12 having a thickness of 30 nm was formed in each sample by sputtering ITO on the substrate 11, which was a glass substrate. Next, a solution containing PEDOT:PSS was applied onto the anode electrode 12 by spin coating, and then the solvent was volatilized by baking. Thus, in each sample, the HIL 13 (PEDOT:PSS layer) having a layer thickness 40 nm was formed. Next, a solution containing PVK was applied on the HIL 13 by spin coating, and then the solvent was volatilized by baking. Thus, in each sample, the HTL 14 (PVK layer) having a layer thickness of 20 nm was formed. Subsequently, the QD dispersion (3K) was applied onto the HTL 14 by spin coating with the concentration adjusted, and then a solvent was volatilized by baking. Thus, the QD layers 15 were formed with a layer thickness of 14 nm for Sample (1), a layer thickness of 19 nm for Sample (2), and a layer thickness of 31 nm for Sample (3). Subsequently, a solution containing ZnO nanoparticles was applied onto the QD layer 15 by spin coating and then a solvent was volatilized by baking. Thus, in each sample, the ETL 16 (ZnO nanoparticle layer) having a layer thickness 65 nm was formed. Next, in each sample, the cathode electrode 17 having a thickness 65 nm was formed on the ETL 16 by vacuum vapor depositing Al. Next, the substrate 11 and the layered body formed on the substrate 11 in each sample were sealed with a sealing member in an N₂ atmosphere.

Subsequently, a current with a current density of 0.03 mA/cm² to 75 mA/cm² was applied to each sample. Then, by applying the current, the luminance of the light L emitted from each sample was measured using the LED measurement device (spectrometer).

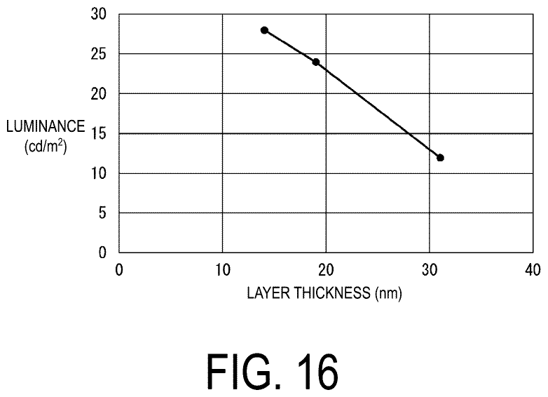

Concentrations of the QD dispersions (3K), the layer thicknesses of the QD layers 15 in the respective samples, and luminance values of the respective samples when the current density of 25 mA/cm² is applied are summarized in Table 1. FIG. 16 shows the luminance values of the respective samples when a current with a current density of 25 mA/cm² is applied.

TABLE 1

| | Concentration of | Layer thickness of | Luminance value at |
|---|---|---|---|
| Sample | QD dispersion | QD layer | 25 mA/cm² |
| (1) | 5 mg/mL | 14 nm | 28 cd/m² |
| (2) | 8 mg/mL | 19 nm | 24 cd/m² |
| (3) | 10 mg/mL | 31 nm | 12 cd/m² |

As shown in Table 1 and FIG. 16, when the layer thickness of the QD layer 15 is 20 nm or less, for example, the luminance value at a current density of 25 mA/cm² is 20 cd/m² or more, indicating that particularly favorable light-emission characteristics are obtained.

### Example 2

Except for changing the HTL 14 and the ETL 16 as shown in Table 2, the same operations as in Example 1 were performed to manufacture three types of light-emitting elements 1 having the following layered structures as Samples (4) to (6).
Sample (4): ITO (30 nm)/PEDOT:PSS (40 nm)/PVK (20 nm)/QD layer (14 nm)/ZnMgO (62 nm)/Al (65 nm)
Sample (5): ITO (30 nm)/PEDOT:PSS (40 nm)/TFB (30 nm)/QD layer (14 nm)/ZnMgO (62 nm)/Al (65 nm)
Sample (6): ITO (30 nm)/PEDOT:PSS (40 nm)/TFB (30 nm)/QD layer (14 nm)/ZnO (65 nm)/Al (65 nm)

Subsequently, a current with a current density of 25 mA/cm² was applied to each sample. Then, by applying the current, the luminance of the light L emitted from each sample was measured using the LED measurement device (spectrometer). The results are summarized in Table 2. Table 2 also shows materials and layer thicknesses of the HTL 14 and the ETL 16 and the luminance value when a current having a current density of 25 mA/cm² is applied in Sample (1) prepared in Example 1.

TABLE 2

| | HTL | HTL layer | ETL | ETL layer | Luminance value at |
|---|---|---|---|---|---|
| Sample | material | thickness | material | thickness | 25 mA/cm² |
| (1) | PVK | 20 nm | ZnO | 65 nm | 28 cd/m² |
| (4) | PVK | 20 nm | ZnMgO | 62 nm | 40 cd/m² |
| (5) | TFB | 30 nm | ZnMgO | 62 nm | 155 cd/m² |
| (6) | TFB | 30 nm | ZnO | 65 nm | 50 cd/m² |

As shown in Table 2, when the HTL 14 contains TFB and the ETL 16 contains ZnMgO, for example, the luminance value at a current density of 25 mA/cm² is 155 cd/m², which is the largest among Sample (1) and Samples (4) to (6), and the luminance is significantly improved. Therefore, it is understood that particularly favorable light-emission characteristics can be obtained when the HTL 14 contains TFB and the ETL 16 contains ZnMgO.

As described above, according to the present embodiment, for example, it is possible to provide the light-emitting element 1 having excellent light-emission characteristics, such as high luminance green fluorescence or red fluorescence.

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

### Application in Display Device

As described above, the light-emitting element 1 is applied as, for example, the light source for the display device. As described above, in the present embodiment, the fluorescence wavelength of the QDs 25 and the fluorescence wavelength of the QD layer 15 can be adjusted within a range of, for example, 500 nm or more and 700 nm or less. Thus, the light-emitting element 1 is preferably applied as, for example, the green light source or the red light source of the display device. The light-emitting element 1 may be a light source that lights up by combining light sources of colors (a red light source, a green light source, and a blue light source) corresponding to pixels (an R pixel, a G pixel, and a B pixel), respectively. The display device utilizing this light source can express an image by a plurality of pixels each including the R pixel, the G pixel, and the B pixel.

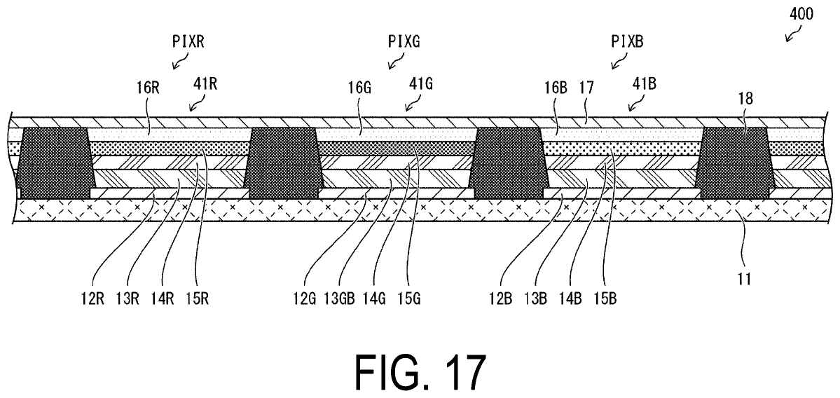

FIG. 17 is a cross-sectional view schematically illustrating an overall configuration of main portions of a display device 400 (light-emitting device) according to the present embodiment.

Note that the present embodiment is described based on a case where the light-emitting device according to the present embodiment is the display device. However, as described above, the light-emitting device according to the present embodiment may be an illumination device such as the LED or the backlight device. The light-emitting device may be used as, for example, a display panel or the light source (illumination device) of the display device 400.

As illustrated in FIG. 17, the display device 400 (light-emitting device) according to the present embodiment includes a plurality of pixels each including the R pixel (PIXR), the G pixel (PIXG), and the B pixel (PIXB). Note that the R pixel may be referred to as an R subpixel. This similarly applies to the G pixel and the B pixel.

In the display device 400, one picture element is constituted by the PIXR, the PIXG, and the PIXB. Further, in the present embodiment, when there is no need to distinguish these pixels PIXR, PIXG, PIXB, the pixels PIXR, PIXG, PIXB are collectively referred to simply as PIX.

The display device 400 has a structure in which a light-emitting element layer including a plurality of kinds of light-emitting elements having different emission wavelengths is provided.

The light-emitting element layer is provided with light-emitting elements corresponding to each PIX. In the PIXR, a light-emitting element 41R is provided as the red light-emitting element. In the PIXG, a light-emitting element 41G is provided as the green light-emitting element. In the PIXB, a light-emitting element 41B is provided as the blue light-emitting element.

As illustrated in FIG. 17, the light-emitting element 41R includes an anode electrode 12R, an HIL 13R, an HTL 14R, a QD layer 15R, an ETL 16R, and the cathode electrode 17. The light-emitting element 41G includes an anode electrode 12G, an HIL 13G, an HTL 14G, a QD layer 15G, an ETL 16G, and the cathode electrode 17. The light-emitting element 41B includes an anode electrode 12B, an HIL 13B, an HTL 14B, a QD layer 15B, an ETL 16B, and the cathode electrode 17.

Each of the light-emitting elements 41R, 41G, and 41B has a configuration similar to that of the light-emitting element 1 illustrated in FIG. 1. Thus, each of the anode electrode 12R, the anode electrode 12G, and the anode electrode 12B has a configuration similar to that of the anode electrode 12 described in the first embodiment. Each of the HIL 13R, the HIL 13G, and the HIL 13B has a configuration similar to that of the HIL 13 described in the first embodiment. Each of the HTL 14R, the HTL 14G, and the HTL 14B has a configuration similar to that of the HTL 14 described in the first embodiment. Each of the ETL 16R, the ETL 16G, and the ETL 16B has a configuration similar to that of the ETL 16 described in the first embodiment.

Each of the QD layer 15R, the QD layer 15G, and the QD layer 15B has a configuration similar to that of the QD layer 15 described in the first embodiment. The above-described QDs 25 are preferably used for at least one of the red QDs and the green QDs used in the PIXR (light-emitting element 41R) and the PIXG (light-emitting element 41G), respectively, and the above-described QDs 25 are more preferably used for both of them. However, the blue QDs used in the PIXB (light-emitting element 41B) are not particularly limited. Note that, for example, ZnS may be used as the blue QDs if the blue QDs is limited to a non-Cd-based material.

These PIXR, PIXG, and PIXB are formed by, for example, separately patterning layers corresponding to respective layers of the light-emitting element 1 including at least the QD layer 15 on the substrate 11 provided with a bank 18 using, for example, an ink-jet method.

Film formation of the ETL 16 may be implemented for each pixel unit or may be implemented in common for the plurality of pixels, provided that the display device 400 can light up the PIXR, PIXG, and PIXB individually.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

1: An electroluminescent element comprising:
a first electrode;
a second electrode; and
a quantum dot light-emitting layer containing a quantum dot and provided between the first electrode and the second electrode,
wherein the quantum dot is a Cd-free quantum dot having a core-shell structure including a core containing at least Ag, Ga, and at least one of S and Se, and a shell containing at least Zn, and exhibits fluorescence characteristics with a fluorescence full-width at half-maximum of 40 nm or less and a fluorescence quantum yield percentage of 70% or more.

2: The electroluminescent element according to claim 1,
wherein the shell further contains at least one of S and Se.

3: The electroluminescent element according to claim 1,
wherein the shell further contains Ga.

4: The electroluminescent element according to claim 1,
wherein the shell includes
a Ga-containing layer containing Ga and at least one of S and Se, and
a Zn-containing layer containing Zn and at least one of S and Se, and
the Ga-containing layer is provided between the core and the Zn-containing layer.

5: The electroluminescent element according to claim 4,
wherein the Ga-containing layer is a GaS layer,
the Zn-containing layer is a ZnS layer, and
the shell has a dual-layer structure of the GaS layer and the ZnS layer.

6: The electroluminescent element according to claim 1,
wherein the shell contains at least one selected from the group consisting of ZnGa₂Se₄ and ZnGa₂S₄.

7: The electroluminescent element according to claim 1,
wherein the quantum dot is formed by forming a Ga-containing layer containing Ga and at least one of S and Se on a surface of the core and then adding Zn.

8: The electroluminescent element according to claim 1,
wherein the quantum dot is formed by forming a GaS layer on a surface of the core and then forming a ZnS layer.

9: The electroluminescent element according to claim 1,
wherein the core and the shell do not contain Cd or In.

10: The electroluminescent element according to claim 1,
wherein a fluorescence wavelength of the quantum dot is in a range from 400 nm to 700 nm.

11: The electroluminescent element according to claim 1,
wherein a layer thickness of the quantum dot light-emitting layer is within a range from 2 nm to 20 nm.

12: The electroluminescent element according to claim 1, comprising:
a hole transport layer provided between an anode electrode and the quantum dot light-emitting layer; and
an electron transport layer provided between a cathode electrode and the quantum dot light-emitting layer,
wherein one of the first electrode and the second electrode is the anode electrode, and another is the cathode electrode,
the hole transport layer contains poly[(9,9-dioctylfluorenyl-2,7-diyl)-co-(4,4′-(N-(4-sec-butylphenyl)diphenylamine))], and
the electron transport layer contains ZnMgO.

13: A light-emitting device comprising:
at least one electroluminescent element according to claim 1.

14: The light-emitting device according to claim 13,
wherein the light-emitting device is a display device.

15: A method for manufacturing an electroluminescent element including a first electrode, a second electrode, and a quantum dot light-emitting layer containing a quantum dot being Cd-free, and provided between the first electrode and the second electrode, the method comprising:
forming the first electrode;
forming the quantum dot light-emitting layer containing the quantum dot;
forming the second electrode; and
synthesizing the quantum dot prior to the forming the quantum dot light-emitting layer,
wherein the synthesizing the quantum dot includes
producing a core containing at least Ag, Ga, and at least one of S and Se, and
forming a shell on a surface of the core, and
in the forming a shell,
a Ga-contained layer containing Ga and at least S and Se is formed on the surface of the core, and then Zn is added.

16: The method for manufacturing an electroluminescent element according to claim 15,
wherein in the forming a shell,
by forming the Ga-containing layer and then adding Zn, a Zn-containing layer containing Zn and at least one of S and Se is formed.

17: The method for manufacturing an electroluminescent element according to claim 16,
wherein in the forming a shell,
a GaS layer is formed as the Ga-containing layer, and then a ZnS layer is formed as the Zn-containing layer.

18: The method for manufacturing an electroluminescent element according to claim 15,
wherein in the synthesizing the quantum dot,
raw materials not containing Cd or In is used as raw materials for the core and the shell.

19: The method for manufacturing an electroluminescent element according to claim 15,
wherein in the synthesizing the quantum dot,
gallium acetylacetonate is used as a Ga raw material.
